(19) United States
(12) Patent Application Publication
(10) Pub. No.: US 2024/0079445 A1
(43) Pub. Date: Mar. 7, 2024

(54) SUPER-JUNCTION MOS DEVICE WITH INTEGRATED TMBS STRUCTURE AND MANUFACTURING METHOD THEREOF

(71) Applicant: Hangzhou Silicon-Magic Semiconductor Technology Co., Ltd, Hangzhou (CN)

(72) Inventors: Jiakun Wang, Hangzhou (CN); Xiao Hongxiu, Hangzhou (CN)

(21) Appl. No.: 17/903,745

(22) Filed: Sep. 6, 2022

(30) Foreign Application Priority Data
Sep. 3, 2022 (CN) 202111032029.4

(51) Int. Cl. H01L 29/06; H01L 29/66; H01L 29/78

(52) U.S. Cl. CPC H01L 29/0634; H01L 29/66734; H01L 29/7813; H01L 29/8725

(57) ABSTRACT

A super-junction MOS device with an integrated TMBS structure and a manufacturing method thereof are provided. The super-junction MOS device includes a main body. The TMBS structure is connected in parallel between at least two cells of the main body.

### FIELD OF DISCLOSURE

The present disclosure relates to semiconductor devices, more particularly, to a super-junction MOS device with an integrated Trench-MOS-Barrier-Schottky (TMBS) structure and a manufacturing method thereof.

### DESCRIPTION OF RELATED ARTS

Super junctions have been widely adopted in medium- and high-voltage power semiconductor devices. In a drift region of a super-junction MOS device, several pairs of P-N pillars, consisting of alternately arranged N pillars and P pillars, form a super junction. When such MOS device is cut off, a corresponding depletion layer extends from each of the P-N junction interfaces between one of the N pillars and one of the P pillars. Since the amount of impurities in the N pillars and the amount of impurities in the P pillars are usually equal, the depletion layers will extend until the N pillars and the P pillars are completely depleted, thus rendering the device high-voltage resistant. Compared with the traditional Vertical-Double-diffused-Metal-Oxide-Semiconductor (VDMOS) power devices, super-junction MOS devices achieve a better balance between voltage resistance and on-resistance.

However, one disadvantage of the common super-junction MOS devices is that their parasitic diodes perform poorly when it comes to reverse recovery, which makes common super-junction devices prone to damages in hard switching applications due to higher peak reverse-recovery currents, making the devices hazardous.

### SUMMARY OF THE DISCLOSURE

The present disclosure provides a super-junction MOS device with an integrated TMBS structure, and the super-junction MOS device includes a main body and a TMBS structure. The main body further includes a plurality of cells. The TMBS structure is integrated in the super-junction MOS device, and is connected in parallel with at least two of the plurality of cells.

Optionally, the main body of the super-junction MOS device further includes:
a substrate, which is of a first doping type;
an epitaxial layer, which is of the first doping type, and is disposed on a surface of the substrate;
a plurality of second pillars, which are of a second doping type, wherein the second doping type is different from the first doping type, and the plurality of second pillars are spaced apart and distributed in the epitaxial layer;
a plurality of super-junction gates, each of which is located in one of a plurality of first pillars of the epitaxial layer, wherein the plurality of first pillars are of the first doping type, wherein each of the plurality of first pillars has one or more of the plurality of super-junction gates located inside it, wherein each of the plurality of super-junction gates includes a trench, a gate oxide layer formed on an inner surface of the trench, and a gate conductor filled in the trench, with the gate oxide layer formed between the trench and the gate conductor, wherein the trench is formed by etching an top surface of the epitaxial layer;
a plurality of wells, which are of the second doping type, wherein one of the wells is formed between every two adjacent super-junction gates and in the epitaxial layer, wherein a depth of the wells is less than a depth of the trench of each super-junction gate;
a plurality of source regions and one or more isolation regions disposed in upper portions of the wells, wherein the source regions are of the first doping type, and at least two of the source regions are on two side of one of isolation regions respectively, wherein each of the source regions has an top surface, which further consists of a first part and a second part, with the first part of the top surface being closer to the isolation region than the second part;
one or more sources, each of which is disposed on an top surface of one of the isolation regions and on the first part of the top surface of one of the source regions;
an insulating oxide layer, disposed on the second part of the top surface of each source region and an top surface of each super-junction gate;
a front metal layer, disposed on a top surface of the insulating oxide layer and a top surface of the one or more sources, to inter-connect the one or more sources; and
a back metal layer, located on a surface of the substrate away from the epitaxial layer.

Optionally, a dopant ion concentration of the isolation regions is higher than a dopant ion concentration of the wells. The dopant ion concentration of the wells is higher than a dopant ion concentration of the second pillars.

Optionally, the TMBS structure includes:
a substrate, which is of the first doping type;
an epitaxial layer, which is of the first doping type and disposed on a surface of the substrate, wherein the epitaxial layer has a top surface including first parts and second parts;
two structural gates, located in the epitaxial layer, wherein each of the structural gates includes a trench, a gate oxide layer formed on an inner surface of the trench, and a gate conductor filled in the trench, with the gate oxide layer formed between the trench and the gate conductor, wherein the trench is formed by etching an top surface of the epitaxial layer, wherein each of the structural gates includes a top surface, which further includes a first part and a second part;
Schottky metal contacts, which cover the first part of the top surface of each structural gate and the first parts of the top surface of the epitaxial layer between the two structural gates;
an insulating oxide layer, disposed on the second part of the top surface of each structural gate and the second parts of the top surface of the epitaxial layer between the two structural gates;
a front metal layer, disposed on top surfaces of the Schottky metal contacts and an top surface of the insulating oxide layer for connecting all the Schottky metal contacts;
and
a back metal layer, disposed on a surface of the substrate away from the epitaxial layer.

Optionally, a distance between the two structural gates is from 0.5 um to 10 um, and a depth of the structural gates is from 1 um to 5 um.

Optionally, the first doping type is N type (i.e., N-type doping), and the second doping type is P type (i.e., P-type doping); or the first doping type is P type and the second doping type is N type.

Optionally, a thickness of the epitaxial layer is between 10 μm and 100 μm, and a resistivity of the epitaxial layer is from 0.1 ohm·cm to 10 ohm·cm.

Optionally, an ion implantation does for forming the substrate is from 1e12 cm² to 1e14 cm2 and an implantation energy is from 10 keV to 200 keV, and a depth of the second pillars is between 8 μm and 90 μm.

The present disclosure further provides a manufacturing method of a super-junction MOS device with an integrated TMBS structure, including:
forming an epitaxial layer on a substrate, wherein the epitaxial layer and the substrate are of the first doping type;
forming a plurality of second pillars in the epitaxial layer, wherein the second pillars are of the second doping type;
performing etching at first predetermined positions of the epitaxial layer to form a plurality of trenches, forming gate oxide layers in the trenches, and filling the trenches formed with the gate oxide layers with gate conductors to form a plurality of super-junction gates and a plurality of structural gates;
performing ion implantation on a top surface of the epitaxial layer between every two adjacent super-junction gates and between one of the super-junction gates and an adjacent structural gate (if any), after which implanted ions are diffused to form wells, wherein the wells are of the second doping type, wherein a depth of the wells is less than a depth of the super-junction gates or the structural gates;
performing ion implantation on top surfaces of the wells that are on two sides of each of the super-junction gates, after which implanted ions are diffused to form source regions, wherein the source regions are of the first doping type;
performing ion implantation on top surfaces of the wells on one side of each of the source regions away from an adjacent super-junction gate, after which implanted ions are diffused to form one or more isolation regions;
forming an insulating oxide layer on top surfaces of the source regions, the isolation regions, the structural gates, and the super-junction gates;
performing etching at second predetermined positions of the insulating oxide layer to form source contact holes, which expose the isolation regions and a part of each source region close to an adjacent isolation region, and to form TMBS contact holes, which expose the two structural gates and the part of the epitaxial layer between the two structural gates of the same TMBS structure, and filling metal in the source contact holes and the TMBS contact holes to respectively form sources and Schottky metal contacts;
forming a front metal layer on top surfaces of the sources, the Schottky metal contacts, and the insulating oxide layer to connect all the sources and all the Schottky metal contacts; and
forming aback metal layer on a surface of the substrate away from the epitaxial layer.

Optionally, the method of forming the second pillars includes: performing etching on third predetermined positions on the epitaxial layer to form a plurality of trenches, and filling all the trenches to form the second pillars; or performing ion implantation on fourth predetermined positions on the epitaxial layer, after which implanted ions are diffused to form the second pillars.

Compared with the related art, the one or more embodiments of the present disclosure have the following beneficial effects:

The super-junction MOS device with an integrated TMBS structure of the present disclosure greatly improves reverse recovery characteristics of the super-junction MOS device, by integrating the TMBS structure, which is connected in parallel with adjacent cells in the main body, and solves the problem that common super-junction devices are prone to damages caused by higher peak reverse-recovery currents, thus increasing the safety of the super-junction MOS device during operation. Also, the TMBS structure is integrated between two or more of the cells in the main body without adding extra process steps, thereby simplifying the processes and reducing the cost.

Other features and advantages of the present disclosure will be explained in the following description, and will partially become apparent from the description or be appreciated by implementing the present disclosure. The objectives and other advantages of the present disclosure may be realized and obtained by structures particularly specified in the description, the appended claims, and the accompanying drawings.

### BRIEF DESCRIPTION OF THE DRAWINGS

The accompanying drawings are included to facilitate understanding of the disclosure, and are incorporated as a part of this specification. The drawings illustrate embodiments of the disclosure and, together with the description, serve to explain the principles of the disclosure in a non-limiting way.

FIG. 1 is a schematic structural cross sectional view of a super-junction MOS device with an integrated TMBS structure according to Embodiment 1 of the present disclosure.

FIG. 2 is a flowchart showing a manufacturing method of a super-junction MOS device with an integrated TMBS structure according to Embodiment 2 of the present disclosure.

FIG. 3 is a schematic cross sectional view of an intermediate structure formed by step S201 of FIG. 2.

FIG. 4 is a schematic cross sectional view of an intermediate structure formed by step S202 of FIG. 2.

FIG. 5 is a schematic cross sectional view of an intermediate structure formed by step S203 of FIG. 2.

FIG. 6 is a schematic cross sectional view of an intermediate structure formed by step S204 of FIG. 2.

FIG. 7 is a schematic cross sectional view of an intermediate structure formed by step S205 of FIG. 2.

FIG. 8 is a schematic cross sectional view of an intermediate structure formed by step S206 of FIG. 2.

FIG. 9 is a schematic cross sectional view of an intermediate structure formed by step S207 of FIG. 2.

FIG. 10 is a schematic cross sectional view of an intermediate structure formed by step S208 of FIG. 2.

FIG. 11 is a schematic cross sectional view of an intermediate structure formed by step S209 of FIG. 2.

FIG. 12 is a schematic cross sectional view of a structure formed by step S210 of FIG. 2.

### DETAILED DESCRIPTION OF THE EMBODIMENTS

The implementation mode of the present disclosure will be described in detail below with reference to the accompanying drawings and embodiments, by means of which, the implementation process regarding how the present disclosure uses technical means to solve the technical problem and achieve the technical effect can be fully understood and implemented accordingly. It should be noted that, unless there is a conflict, respective embodiments in the present disclosure and respective features in the respective embodiments can be combined with each other, technical solutions resulted from which are also within the scope of the present disclosure.

One disadvantage of the common super-junction MOS devices is that their parasitic diodes perform poorly when it comes to reverse recovery, which makes common super-junction devices prone to damages in hard switching applications due to higher peak reverse-recovery currents, making the devices hazardous.

### Embodiment 1

In light of the above-mentioned technical problems, the present disclosure provides a super-junction MOS device with an integrated TMBS structure.

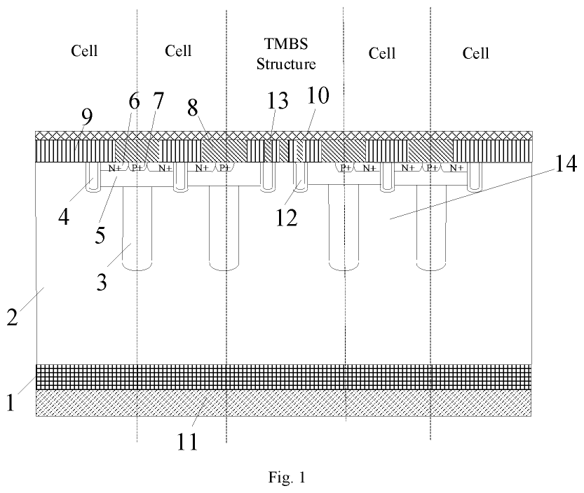

FIG. 1 is a schematic structural cross sectional view of a super-junction MOS device with an integrated TMBS structure according to Embodiment 1 of the present disclosure. As shown in FIG. 1, the super-junction MOS device with an integrated TMBS structure includes a main body and at least one TMBS structure integrated in the super-junction MOS device. The main body includes a plurality of cells, and each of the one or more TMBS structures is connected in parallel between two adjacent cells of the main body. Specifically, each TMBS structure may be disposed between two cells of the main body, or may be disposed among more than two cells of the main body.

Specifically, the main body includes a substrate 1, an epitaxial layer 2 formed on the substrate 1, and a plurality of second pillars 3 formed in the epitaxial layer 2. The substrate 1 is of a first doping type, the epitaxial layer 2 is of the first doping type, and the plurality of second pillars 3 are of a second doping type. Pillar-like regions of the epitaxial layer 2 between the second pillars are herein referred to as first pillars 14, thereby forming a super-junction structure consisting of alternatively arranged N pillars and P pillars. The second doping type is different from the first doping type. Each of the first pillars 14 has a super junction gate 4 disposed therein, and each super-junction gate 4 includes a trench 15, a gate oxide layer 16 disposed in the trench 15, and a gate conductor 17 filled in the trench 15, with the gate oxide layer 16 formed between the trench 15 and the gate conductor 17. In addition, the trenches 15 are formed by etching predetermined positions on a surface of the epitaxial layer 2. Wells 5 are further formed in the epitaxial layer 2 and one of the wells 5 is formed between each two adjacent super-junction gates 4. It should be noted that a depth of the wells 5 is less than a depth of the trenches 15. Source regions 6 and an isolation region 7 are formed on a top surface of each of the second doping type well 5 between the super-junction gates 4. The source regions 6 are of the first doping type. The source regions 6 are located on two sides of the isolation region 7. The isolation region 7 blocks ion flows from the source regions 6 at two sides of the isolation region 7. Each of the source regions 6 has a top surface, which further consists of a first part and a second part, with the first part of the top surface being closer to the isolation region 7 than the second part. At least one source 8 is formed on a top surface of the isolation region 7 and the first part of the top surface of one of the source regions 6. An insulating oxide layer 9 is formed on a top surface of each super-junction gate 4 and the second part of the top surface of each of the source regions 6. A front metal layer 10 is formed on a top surface of the insulating oxide layer 9 and a top surface of the at least one source 8 for connecting the sources in all the cells of the super-junction MOS device. A back metal layer 11 is formed on a surface of the substrate 1 away from the epitaxial layer 2.

In one example, a dopant ion concentration of the isolation regions 7 is higher than a dopant ion concentration of the wells 5, and the dopant ion concentration of the wells 5 is higher than a dopant ion concentration of the second pillars 3.

In one example, the TMBS structure is a region of the main body 1, in which case the TMBS structure shares the substrate 1 and the epitaxial layer 2 with the main body. In other examples, the TMBS structure is separated from the main body 1, in which case the TMBS includes a substrate and an epitaxial layer located on a surface of the substrate, and during the device manufacturing process, the substrate and the epitaxial layer of the TMBS structure can be formed simultaneously with the substrate 1 and the epitaxial layer 2 of the main body. Each of the TMBS structures further includes two structural gates 12. The structural gates 12 are located in the epitaxial layer 2. Each of the structural gates 12 includes a trench, a gate oxide layer disposed on the inner surface of the trench, and a gate conductor filled in the trench, with the gate oxide layer formed between the gate conductor and the trench; and the trenches are formed by etching a top surface of the epitaxial layer. It should be noted that, the structural gates 12 have the same structure of the super-junction gates 4, as can be seem from the above description, and therefore, the structural gates 12 and the super-junction gates 4 may also be formed at the same time during the manufacturing process. The TMBS structure further includes Schottky metal contacts 13 and an insulating oxide layer (same or substantially the same as the insulating oxide layer 9 of the main body 1). Each of the structural gates 12 includes a top surface, which further includes a first part and a second part. The epitaxial layer of the TMBS structure has a top surface including first parts and second parts. The Schottky metal contacts 13 cover the first part of the top surface of each structural gate 12 and the first parts of the top surface of the epitaxial layer between the two structural gates 12. The insulating oxide layer of the TMBS structure is disposed on the second part of the top surface of each structural gate 12 and the second parts of the top surface of the epitaxial layer between the two structural gates 12. The Schottky metal contacts 13 are formed by first etching to obtain TMBS contact holes in the insulating oxide layer of the TMBS structure and then filling the TMBS contact holes with metal. Additionally, during the manufacturing process, the insulating oxide layer of the TMBA structure and the insulating oxide layer 9 of the main body can also be formed at the same time.

In one example, the TMBS structure further includes a front metal layer and a back metal layer. The front metal layer located on top surfaces of the Schottky metal contacts 13 and the top surface of the insulating oxide layer for connecting all the Schottky metal contacts 13. The back metal layer is located on the surface of the substrate away from the epitaxial layer. In one example, during the manufacturing process, the front metal layer of the TMBS structure and the front metal layer 10 of the main body are simultaneously formed, and are made of the same materials; the back metal layer of the TMBS structure and the back metal layer 11 of the main body are also simultaneously formed and are made of the same materials. In some examples, the main body and the TMBS structure share one front metal layer and one back metal layer, which facilitates parallel connection between the TMBS structure and the main body in a simplified manner.

In one example, a distance between the two structural gates 12 of the same TMBS structure can be correspondingly designed depending on the maximum voltage difference between the two terminals of the TMBS structure and a depth the second pillars 3. The distance between the two structural gates 12 of the same TMBS structure is, for example, from 0.5 um to 10 um, and a depth of the structural gates is, for example, from 1 um to 5 um.

The present disclosure introduces at least one TMBS structure into a regular super-junction MOS device, with the former being positioned between adjacent cells of the MOS device. When a forward voltage is applied to two terminals of the TMBS structure, positive charges accumulate on surfaces of the structural gates 12, and attract electrons to the surfaces, thus realizing overcurrent. When a reverse voltage is applied to the two terminals of the TMBS structure, the surfaces of the structural gates 12 attract holes, and the structural gates 12 and the epitaxial layer 2 forms a depletion region, thereby realizing voltage resistance. The introduction of the TMBS structure into the super-junction MOS device greatly improves reverse-recovery-related characteristics of the device and improves the safety of the super-junction MOS device during use.

The doping type of a material layer is determined by what impurity atoms are doped into a neutral substrate to form the material layer. For example, N-type doping can be achieved by doping group-V elements such as nitrogen, phosphorus, and arsenic (i.e. donors, which provide valence electrons) into a germanium- or silicon-based semiconductor substrate. P-type doping can be achieved by doping group-III elements such as boron and aluminum (i.e., acceptors, which accept valence electrons) into a germanium or silicon-based semiconductor substrate. For example, as shown in FIG. 1, in one embodiment, an N-type semiconductor substrate, such as a silicon substrate or a germanium substrate doped with group-V elements such as nitrogen, phosphorus, and arsenic, can be adopted as the substrate 1, in which case the second pillars 3 are P-type pillars, and they includes, for example, polysilicon doped with group-III elements, such as boron and aluminum. Of course, in another example, a P-type semiconductor substrate can be adopted as the substrate 1, in which case the second pillars 3 are N-type pillars. In some practical applications, the N-type semiconductor substrate is preferred. For example, an N-type silicon substrate or germanium substrate is adopted to form NMOS transistors because its on-resistance is smaller and its manufacturing process is simpler. The substrate 1 is a heavily doped substrate, and a doping concentration of the epitaxial layer 2 is usually lower than that of the substrate 1. The thickness of the epitaxial layer 2 determines the punch-through voltage of the device. Theoretically, the thicker the epitaxial layer 2 the higher the punch-through voltage. However, the device will be too bulky if it is too thick. In one example, the thickness of the epitaxial layer 2 is between 10 μm and 100 μm, and its resistivity ranges from 0.1 ohm·cm to 10 ohm·cm. As an example, the depth of the second pillars 3 is between 8 um and 90 um, and an ion implantation does for forming the substrate 1 is from 1e12 cm² to 1e14 cm² and an implantation energy is from 10 keV to 200 keV.

In one example, a material of the gate conductor 17 is polysilicon; polysilicon is relatively resistant to high temperature and there are fewer defects in interfaces between the gate oxide layer 16 and a polysilicon-based gate conductor 17. In addition, the work function of the gate conductor 17 can be changed by doping impurities of different polarities to reduce the threshold voltage of the device. The gate oxide layer 16 is for isolation between the gate conductors 17 and the wells 5. In order to ensure that the gate conductor 17 is sufficiently voltage resistant, a thickness of the gate oxide layer 16 is preferably greater than 500 angstroms (Å), and its material may be one or more of silicon dioxide, nitride, and oxynitride. In one example, the gate oxide layer 16 is formed by a thermal oxidation process. In another example, the gate conductor 17 may be made of metal or metal silicide.

In one example, the front metal layer 10 is connected with the sources 8, and the Schottky metal contacts 13, which improves electrical connections between the components. In some examples, the front metal layer 10 and the sources 8 may be made of the same materials and may be formed in the same process; in some examples, the sources 8 and the Schottky metal contacts 13 may also be made of the same materials and formed in the same process, which simplifies the manufacturing process. A material of the front metal layer 10 is may be aluminum, copper, or copper-aluminum alloy, and a material of the sources 8 and the Schottky metal contacts 13 may be one or more of titanium, titanium nitride, and aluminum.

In one example, the super-junction MOS device further includes a buffer layer (not shown in the figured) disposed between the substrate 1 and the epitaxial layer 2, wherein the buffer layer is of the first doping type. A doping concentration of the buffer layer may be between the doping concentrations of the substrate 1 and the epitaxial layer 2. The buffer layer serves to prevent the impurity atoms of the substrate 1 from diffusing into the epitaxial layer 2 during subsequent high temperature processes, and prevent the doping concentration of the epitaxial layer 2 (especially that of the first pillars 14) from increasing, and an increase in the doping concentration of the epitaxial layer 2 will lead to a decrease in the punch through voltage of the device.

In one example, there are spaces between lower surfaces of the second pillars 3 and the substrate 1, and the epitaxial layer 2 between the lower surfaces of the second pillars 3 and the substrate 1 serves as a buffer layer, thus eliminating the need for an extra buffer layer.

It should be noted that the structures of both the main body and the TMBS structure are not limited to embodiments described herein.

The super-junction MOS device with an integrated TMBS structure according to the present disclosure has great reverse-recovery-related characteristics, which are achieved by the integrated TMBS structure connected in parallel between some of the cells of the main body, thereby solving the problem that common super-junction devices are prone to damages in hard switching applications due to higher peak reverse-recovery currents. As a result, the super-junction MOS device of the present disclosure is safer to use. Additionally, the TMBS structure is integrated between two or more of the cells of the main body once the TMBS structure and the main body are simultaneously formed, thereby simplifying the processes and reducing the cost.

### Embodiment 2

The present disclosure further provides a manufacturing method of a super-junction MOS device with an integrated TMBS structure. In some examples, the method is applicable to the super-junction MOS device with an integrated TMBS structure described above in Embodiment 1.

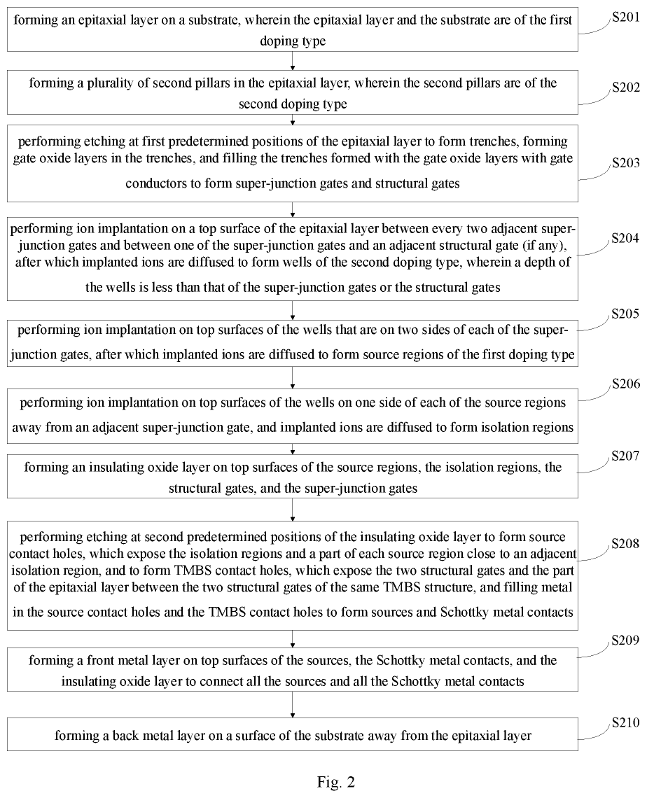

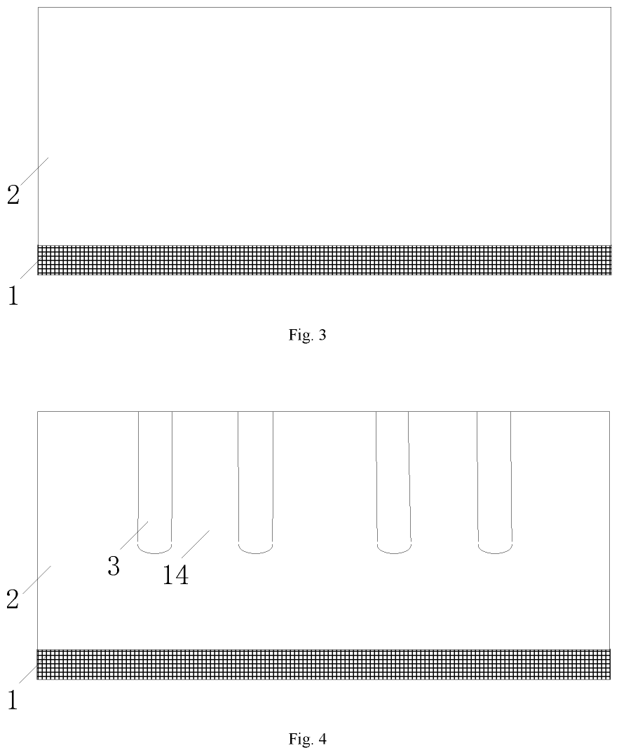

FIG. 2 is a flowchart showing a manufacturing method of a super-junction MOS device with an integrated TMBS structure according to Embodiment 2 of the present disclosure. Hereinafter, the second doping type is P type when the first doping type is N type, and the second doping type is N type when the first doping type is P type. FIG. 3 to FIG. 12 show schematic cross sectional views of the intermediate structures formed by various steps according to one embodiment of the present disclosure, and the structures shown in FIG. 3 to FIG. 12 correspond to situations where the first doping type is N type and the second doping type is P type, which is only one example of the method of the present embodiment. Referring to FIG. 2 to FIG. 12, the manufacturing method of the super-junction MOS device with an integrated TMBS structure according to the present disclosure includes steps S201-S210 as described below.

Step S201: a substrate 1 is provided, and an epitaxial layer 2 is formed on a surface of the substrate 1. The substrate 1 is of the first doping type, and the epitaxial layer 2 is of the first doping type.

In one example, the epitaxial layer 2 is formed by vapor deposition. During the deposition process, a desired doping concentration is achieved by adjusting the concentration of corresponding impurity atoms. A doping concentration of the epitaxial layer 2 is preferably lower than that of the substrate 1. A schematic cross sectional view of the intermediate structure formed by this step is shown in FIG. 3.

Step S202: a plurality of second pillars 3 is formed in the epitaxial layer 2. The second pillars 3 are of the second doping type.

In one example, the plurality of second pillars 3 may be formed by etching at third predetermined positions on the epitaxial layer 2 to form a plurality of trenches and then filling all the trenches. The plurality of second pillars 3 may also be formed by implanting ions at fourth predetermined positions on the epitaxial layer 2 and subsequent diffusion of the ions. The third predetermined positions and the fourth predetermined positions are both used to refer to positions on the epitaxial layer 2 related to forming the second pillars 3. However, since ion diffusion usually occurs after ion implantation, the third predetermined positions are not exactly the same as the fourth predetermined positions. A schematic cross sectional view of the intermediate structure formed by this step is shown in FIG. 4.

Step S203: Etching is performed at first predetermined positions on the epitaxial layer 2 to form a plurality of trenches 15, a gate oxide layer 16 is then formed in each of the trenches 15, and each of the trenches 15 is filled with a gate conductor 17, with the gate oxide layer 16 formed between the trench 15 and the gate conductor 17, thereby forming a plurality of super-junction gates 4 and a plurality of structural gates 12.

The first predetermined positions are positions on the epitaxial layer 2 where the super-junction gates 4 and the structural gates 12 need to be formed. The method for forming the gate oxide layer 16 may be thermal oxidation or vapor deposition. A material of the gate conductors 17 is preferably polysilicon; polysilicon is relatively resistant to high temperature and there are fewer defects in interfaces between the gate oxide layer 16 and a polysilicon-based gate conductor 17. In addition, the work function of the gate conductor 17 can be changed by doping impurities of different polarities to reduce the threshold voltage of the device. The gate oxide layer 16 is for realizing the isolation between the gate conductor 17 and wells 5 that are subsequently formed. In order to ensure that the gate conductor 17 is sufficiently voltage resistant, a thickness of the gate oxide layer 16 is preferably greater than 500 angstroms (Å), and its material may be one or more of silicon dioxide, nitride, and oxynitride. In one example, the gate oxide layer 16 is formed by a thermal oxidation process. In another example, the gate conductor 17 may be made of metal or metal silicide.

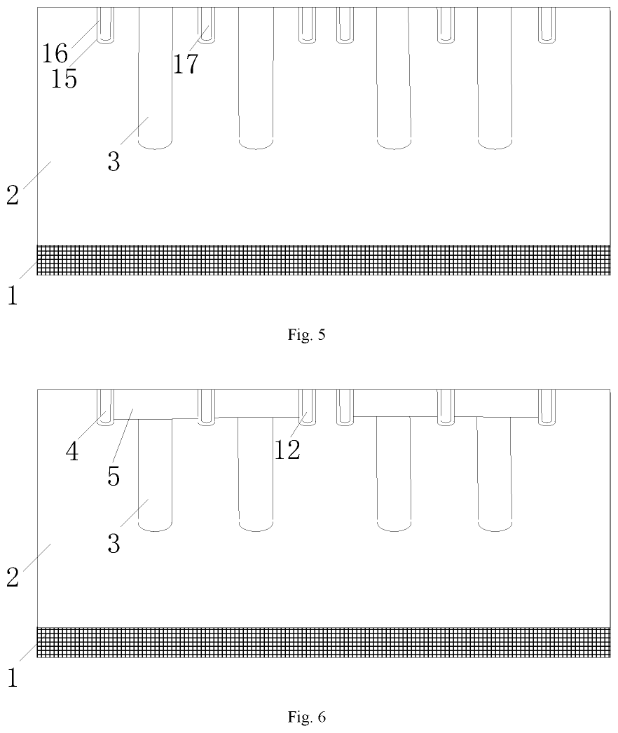

Depending on the actual materials of the epitaxial layer 2, wet or dry etching may be used to form the trenches 15. Of course, those skilled in the art can understand that, this step usually requires a photomask to perform photolithography on a photoresist layer on the epitaxial layer 2 so as to define positions and shapes of the trenches 15, and then the trenches 15 are formed by etching. In the present embodiment, a depth of the trenches 15 is less than a thickness of the epitaxial layer 2. As a result, there are spaces between the trenches 15 and the substrate 1. The portions of the epitaxial layer 2 located between the trenches 15 and the substrate 1 serves as a buffer layer between subsequently formed first pillars 14 and the substrate 1. Of course, in other examples, if a buffer layer is formed between the epitaxial layer 2 and the substrate 1, the depth of the trenches 15 may be the same as the thickness of the epitaxial layer 2. A buffer layer can prevent impurities of the substrate 1 from diffusing into the first pillars 14 during subsequent high temperature processes. A schematic cross sectional view of the intermediate structure formed by this step is shown in FIG. 5.

Step S204: Ion implantation is performed on a top surface of the epitaxial layer 2 between every two adjacent super-junction gates 4 and between one of super-junction gates 4 and an adjacent structural gate 12 (if any), after which implanted ions are diffused to form the wells 5. A depth of the wells 5 is less than a depth of the super-junction gates 4 or that of the structural gates 12. The wells 5 are of the second doping type.

In one example, impurity atoms of the second doping type are implanted into the top surface of the epitaxial layer 2 between every two adjacent super-junction gates 4 and between one of the super-junction gates 4 and an adjacent structural gate 12 (if any), and a high-temperature drive-in process is performed, such as annealing at a high temperature of 1000-1200° C. for 1-10 hours (depending on parameters including doping concentration, depth, and device size, etc.). The wells 5 are formed after the ion implantation and the high-temperature drive-in process. Each of the wells 5 is connected to the gate oxide layer 16, and the depth of the wells 5 is less than the depth of the super-junction gates 4. A schematic cross sectional view of the intermediate structure formed by this step is shown in FIG. 6.

Step S205: Ion implantation is performed on a top surface of each of the wells 5 on two sides of each of the super-junction gates 4, after which implanted ions are diffused to form source regions 6, with the source regions 6 being of the first doping type.

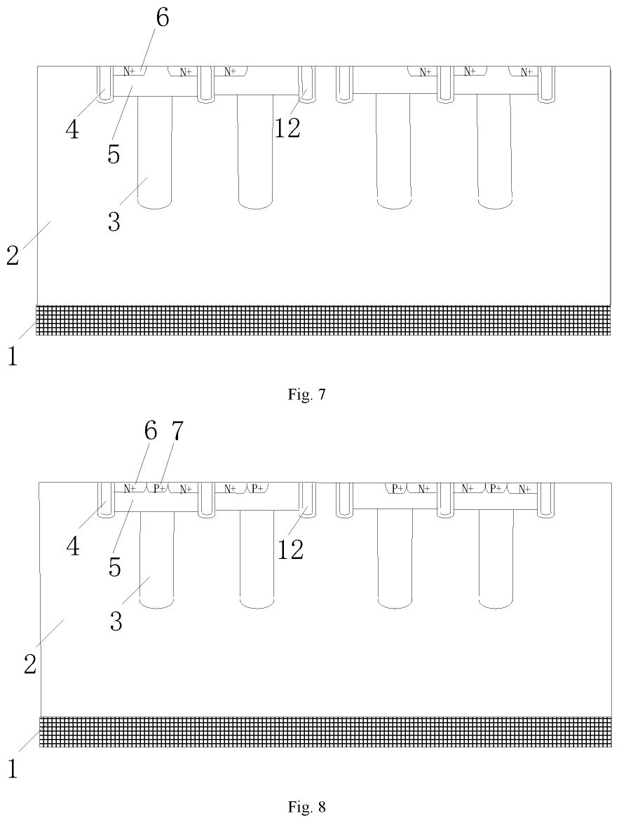

In one example, impurity atoms of the first doping type are implanted into the top surface of each of the wells 5 on two sides of each of the super-junction gates 4, and a high-temperature drive-in process is then performed to form the source regions 6. Each of the source regions 6 is connected to the gate oxide layer 16, and a depth of the source regions 6 is less than the depth of the wells 5. A schematic cross sectional view of the intermediate structure formed by this step is shown in FIG. 7.

Step S206: Ion implantation is performed on the top surface of each of the wells 5 on one side of each of source regions 6 away from an adjacent super-junction gate 4, after which implanted ions are diffused to form one or more isolation regions 7; as a result, in some examples, one of the isolation regions 7 is formed between two of the source regions 6. In some examples, there are several isolation regions 7 formed in the device.

In one example, impurity atoms of the second doping type are implanted into the top surface of each of the wells 5 on one side of each of source regions 6 away from an adjacent super-junction gate 4 and a high-temperature drive-in process is performed to form the isolation regions 7. One of the isolation regions 7 is formed between two of the source regions 6, and the two sides of each isolation region 7 are in contact with and connected to two of the source regions 6. A schematic cross sectional view of the intermediate structure formed by this step is shown in FIG. 8.

Step S207: An insulating oxide layer 9 is formed on top surfaces of the source regions 6, the isolation regions 7, the structural gates 12, and the super-junction gates 4.

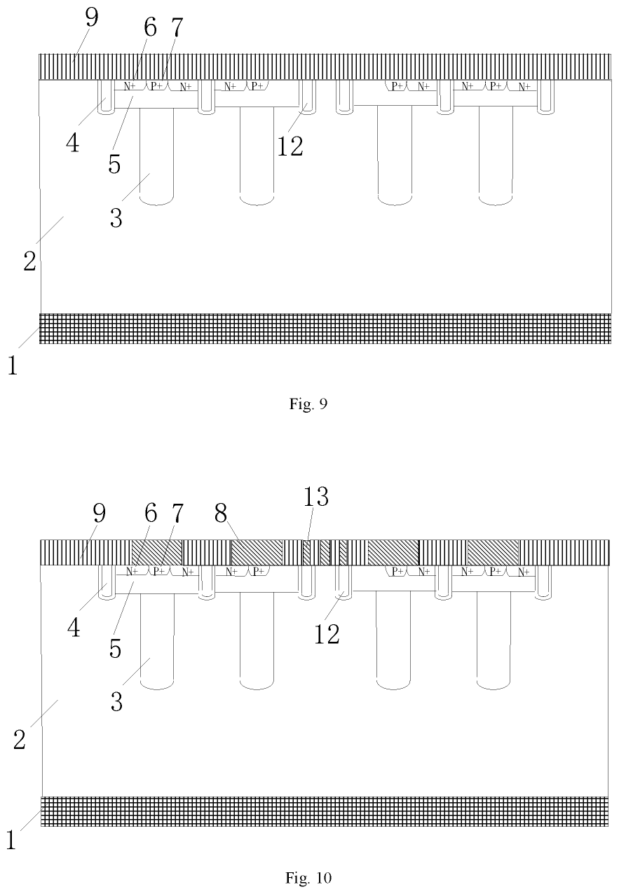

In one embodiment, the same method for forming the gate oxide layer 16 is adopted to form the insulating oxide layer 9. A schematic cross sectional view of the intermediate structure formed by this step is shown in FIG. 9.

Step S208: Etching is performed at second predetermined positions of the insulating oxide layer 9 to form source contact holes (not shown in the figures), wherein the source contact holes expose the isolation regions 7 and a part of each of the source regions 6 close to an adjacent isolation region 7, and to form TMBS contact holes (not shown in the figures), wherein the TMBS contact holes expose the structural gates 12 and the part of the epitaxial layer 2 between the two structural gates 12 of the same TMBS structure, and metal is filled in the source contact holes (not shown in the figures) and the TMBS contact holes (not shown in the figures) to respectively form sources 8 and Schottky metal contacts 13.

The second predetermined positions are positions on the insulating oxide layer 9 where the sources 8 and the Schottky metal contacts 13 need to be formed. The sources 8 and the Schottky metal contacts 13 may have the same materials and may be formed in the same process. In one example, the sources 8 and the Schottky metal contacts 13 are made of one or more of titanium, titanium nitride, and aluminum, and the sources 8 and the Schottky metal contacts 13 may be formed by physical vapor deposition or electroplating process. A schematic cross sectional view of the structure formed by this step is shown in FIG. 10.

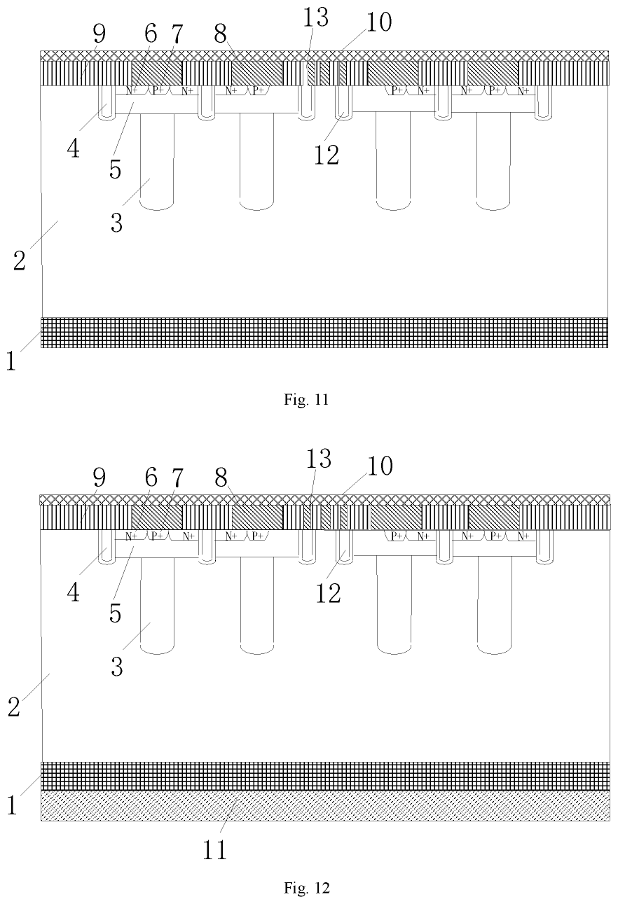

Step S209: A front metal layer 10 is formed on top surfaces of the insulating oxide layer 9, the sources 8, and the Schottky metal contacts 13 for connecting all the sources 8 and all the Schottky metal contacts 13. A schematic cross sectional view of the structure formed by this step is shown in FIG. 11.

Step S210: A back metal layer 11 is formed on a surface of the substrate 1 away from the epitaxial layer 2.

In one example, a material of the front metal layer 10 is aluminum, copper or copper-aluminum alloy, and the front metal layer 10 and the back metal layer 11 may be formed by physical vapor deposition or electroplating process. A schematic cross sectional view of the structure formed by this step is shown in FIG. 12.

The manufacturing method of the super-junction MOS device with an integrated TMBS structure according to the present disclosure greatly improves reverse-recovery-related characteristics of the super-junction MOS device by integrating the TMBS structure, which is connected in parallel between some of the cells of the main body, thereby solving the problem that common super-junction devices are prone to damages in hard switching applications due to higher peak reverse-recovery currents. As a result, the super-junction MOS device of the present disclosure is safer to use. Additionally, the TMBS structure is integrated between two or more of the cells of the main body once the TMBS structure and the main body are simultaneously formed, thereby simplifying the processes and reducing the cost.

In the description of the present disclosure, it should be noted that term such as “first”, “second”, “third”, “fourth” and “fifth” are only used for the purpose of description, and should not be construed as indicating or implying relative importance.

The embodiments disclosed by the present disclosure are provided for better understanding of the present disclosure rather than to limit the present disclosure. Anyone skilled in the art, without departing from the spirit or scope of the present disclosure, can make amendments or modification to implementation manners and details of the embodiments. The scope of protection of the present disclosure, however, must still be as defined by the appended claims.

1. A super-junction MOS device with an integrated TMBS structure, comprising a main body and a TMBS structure, wherein the main body comprises a plurality of cells, and wherein the TMBS structure is connected in parallel with and integrated between at least two of the plurality of cells.

2. The super-junction MOS device as claimed in claim 1, wherein the main body further comprises:
a substrate, wherein the substrate is of a first doping type;
an epitaxial layer disposed on a surface of the substrate, wherein the epitaxial layer is of the first doping type;
a plurality of second pillars spaced apart and distributed in the epitaxial layer, wherein the plurality of second pillars is of a second doping type, wherein pillar-like regions of the epitaxial layer between two of the plurality of second pillars are first pillars, wherein the first pillars are of the first doping type, and the second doping type is different from the first doping type;
a plurality of super-junction gates disposed in the first pillars respectively, wherein each of the plurality of super-junction gates comprises a trench, a gate oxide layer formed on an inner surface of the trench, and wherein a gate conductor fills in the trench, wherein the gate oxide layer is formed between the trench and the gate conductor, and wherein the trench is formed by etching an top surface of the epitaxial layer;
a plurality of wells, which are of the second doping type, wherein one of the plurality of wells is formed in the epitaxial layer between every two adjacent super-junction gates, and wherein a depth of one of the plurality of wells is less than a depth of the trench of each of the plurality of super-junction gates;
a plurality of source regions, wherein one or more isolation regions disposed in upper portions of the plurality of wells, wherein the plurality of source regions is of the first doping type, wherein at least two of the source regions are on two sides of one of the isolation regions respectively, wherein each of the plurality of source regions has a top surface, which further comprises a first part and a second part, wherein the first part of the top surface is closer to the isolation region than the second part;
one or more sources, wherein each of the one or more sources is disposed on a top surface of one of the isolation regions and on the first part of the top surface of one of the plurality of source regions;
an insulating oxide layer, disposed on the second part of the top surface of each of the plurality of source regions and on a top surface of each of the plurality of super-junction gates;
a front metal layer, disposed on a top surface of the insulating oxide layer and a top surface of the one or more sources, wherein the front metal layer inter-connects the one or more sources; and
a back metal layer, disposed on a surface of the substrate away from the epitaxial layer.

3. The super-junction MOS device of claim 2, wherein a dopant ion concentration of the isolation regions is higher than a dopant ion concentration of the plurality of wells, wherein the dopant ion concentration of the plurality of wells is higher than a dopant ion concentration of the plurality of second pillars.

4. The super-junction MOS device of claim 1, wherein the TMBS structure comprises:
a substrate, wherein the substrate is of a first doping type;
an epitaxial layer, wherein the epitaxial layer is of the first doping type and is disposed on a surface of the substrate;
two structural gates, located in the epitaxial layer, wherein each of the structural gates comprises a trench, a gate oxide layer formed on an inner surface of the trench, and a gate conductor filled in the trench, with the gate oxide layer formed between the trench and the gate conductor, wherein the trench is formed by etching a top surface of the epitaxial layer, wherein each of the structural gates comprises a top surface, which further comprises a first part and a second part;
Schottky metal contacts, which cover the first part of the top surface of each of the structural gates and the first parts of the top surface of the epitaxial layer between the two structural gates;
an insulating oxide layer, disposed on the second part of the top surface of each of the structural gates and the second part of the top surface of the epitaxial layer between the two structural gates;
a front metal layer, disposed on top surfaces of the Schottky metal contacts and a top surface of the insulating oxide layer for connecting all the Schottky metal contacts; and
a back metal layer, disposed on a surface of the substrate away from the epitaxial layer.

5. The super-junction MOS device of claim 4, wherein a distance between the two structural gates is set at from 0.5 μm to 10 μm, and a depth of each of the structural gates is from 1 μm to 5 μm.

6. The super-junction MOS device of claim 2, wherein the first doping type is N type and the second doping type is P type, or the first doping type is P type and the second doping type is N type.

7. The super-junction MOS device of claim 4, wherein the first doping type is N type and the second doping type is P type, or the first doping type is P type and the second doping type is N type.

8. The super-junction MOS device of claim 2, wherein a thickness of the epitaxial layer is between 10 μm and 100 μm, and a resistivity of the epitaxial layer is from 0.1 ohm·cm to 10 ohm·cm.

9. The super-junction MOS device of claim 4, wherein a thickness of the epitaxial layer is between 10 μm and 100 μm, and a resistivity of the epitaxial layer is from 0.1 ohm·cm to 10 ohm·cm.

10. The super-junction MOS device of claim 2, wherein an ion implantation dose for forming the substrate is from 1e12 cm² to 1e14 cm² and an implantation energy is from 10 keV to 200 keV, and a depth of one of the plurality of the second pillars is between 8 μm and 90 m.

11. The super-junction MOS device of claim 4, wherein an ion implantation dose for forming the substrate is from 1e12 cm² to 1e14 cm² and an implantation energy is from 10 keV to 200 keV, and a depth of one of the plurality of the second pillars is between 8 μm and 90 μm.

12. A manufacturing method of the super-junction MOS device with an integrated TMBS structure of claim 2, comprising:
forming the epitaxial layer on the substrate;
forming the plurality of second pillars in the epitaxial layer;
performing etching at first predetermined positions of the epitaxial layer to form a plurality of trenches, forming the gate oxide layer in each of the plurality of trenches, and filling each of the plurality of trenches with the gate conductor with the gate oxide layer formed between the gate conductor and the plurality of trenches, to form the plurality of super-junction gates and the plurality of structural gates;
performing ion implantation on a top surface of the epitaxial layer between every two adjacent of the plurality of super-junction gates and between one of the plurality of super-junction gates and any adjacent ones of the plurality of structural gates, wherein the implanted ions are diffused to form the plurality of wells, wherein the plurality of wells are of the second doping type, wherein a depth of one of the plurality of wells is less than a depth of one of the plurality of super-junction gates or one of the plurality of structural gates;
performing ion implantation on top surfaces of the plurality of wells that are on two sides of each of the plurality of super-junction gates, wherein the implanted ions are diffused to form the plurality of source regions, wherein the plurality of source regions are of the first doping type;
performing ion implantation on top surfaces of the plurality of wells on one side of each of the plurality of source regions away from an adjacent one of the plurality of super-junction gates, wherein the implanted ions are diffused to form the one or more isolation regions;
forming the insulating oxide layer on top surfaces of the plurality of source regions, the one or more isolation regions, the plurality of structural gates, and the plurality of super-junction gates;
performing etching at second predetermined positions of the insulating oxide layer to form source contact holes, which expose the isolation regions and a part of each of the plurality of source regions close to an adjacent one of the isolation regions, and to form TMBS contact holes, which expose the two of the plurality of structural gates and the part of the epitaxial layer between the two structural gates of a same TMBS structure, and filling metal in the source contact holes and the TMBS contact holes to respectively form the sources and Schottky metal contacts;
forming the front metal layer on top surfaces of the sources, the Schottky metal contacts, and the insulating oxide layer for connecting all the sources and all the Schottky metal contacts; and
forming the back metal layer on the surface of the substrate away from the epitaxial layer.

13. The manufacturing method of claim 12, wherein the method of forming the plurality of second pillars comprises:
performing etching at third predetermined positions on the epitaxial layer to form the plurality of trenches, and performing filling to all the plurality of trenches to form the plurality of second pillars; or
performing ion implantation at fourth predetermined positions on the epitaxial layer, wherein the implanted ions are diffused to form the plurality of second pillars.
